(19) United States
(12) Patent Application Publication
(10) Pub. No.: US 2018/0250788 A1
(43) Pub. Date: Sep. 6, 2018

(54) SPIRAL AND CONCENTRIC MOVEMENT DESIGNED FOR CMP LOCATION SPECIFIC POLISH (LSP)

(71) Applicant: Applied Materials, Inc., Santa Clara, CA (US)

(72) Inventors: Eric LAU, Santa Clara, CA (US); Chih Chung CHOU, San Jose, CA (US); Charles C. GARRETSON, Sunnyvale, CA (US); Jeonghoon OH, Saratoga, CA (US); King Yi HEUNG, Union City, CA (US)

(21) Appl. No.: 15/891,722

(22) Filed: Feb. 8, 2018

Related U.S. Application Data
(60) Provisional application No. 62/467,672, filed on Mar. 6, 2017.

(51) Int. Cl. B24B 7/22; B24B 13/005; B24B 49/10; B24B 37/07

(52) U.S. Cl. CPC B24B 7/228; B24B 13/005; H01L 21/304; B24B 37/07; B24B 49/10

(57) ABSTRACT

A method is provided to minimize travel distance and time between correction locations on a substrate when polishing a local area of a substrate, such as a semiconductor wafer, using a location specific polishing module. A correction profile is determined and a recipe based on the correction profile is used to polish a substrate. A polishing pad assembly traverses between a first correction location and a second correction location using the combined motion of a substrate support chuck and a support arm coupled at a first end thereof to the polishing pad assembly. The chuck rotates about a center axis thereof. The positioning arm may sweep about a vertical axis disposed through a second end of the support arm. The combined motion of the chuck and the positioning arm causes the polishing pad assembly to form a spiral shaped polishing path on the substrate.

### CROSS REFERENCE TO RELATED APPLICATIONS

This application claims priority to U.S. Provisional Patent Application Ser. No. 62/467,672 filed Mar. 6, 2017 which is herein incorporated by reference in its entirety.

### BACKGROUND

### Field

Embodiments of the present disclosure generally relate to methods for polishing a substrate, such as a semiconductor wafer, and more particularly, to methods for polishing specific locations or regions of a substrate in an electronic device fabrication process.

### Description of the Related Art

Chemical mechanical polishing (CMP) is a process which is commonly used in the manufacture of high-density integrated circuits to planarize or polish a layer of material deposited on a substrate, by contacting the material layer to be planarized with a polishing pad and moving the substrate, and hence the material layer surface, with respect to the polishing pad in the presence of a polishing fluid such as a slurry. In a typical polishing process, the substrate is retained in a carrier head that presses the backside of the substrate toward the polishing pad. Material is removed across the material layer surface in contact with the polishing pad through a combination of chemical and mechanical activity. The carrier head may contain multiple individually controlled pressure regions that apply differential pressure to different annular regions of the substrate. For example, if greater material removal is desired at the peripheral region of the substrate as compared to the desired material removal at the center of the substrate, the carrier head will apply more pressure to the peripheral region of the substrate. However, the stiffness of the substrate tends to redistribute the pressure applied to local regions of the substrate by the carrier head such that the pressure applied to the substrate may be spread or smoothed generally across the entire substrate. The smoothing effect makes local pressure application, for local material removal, difficult if not impossible.

Two common applications of CMP are planarization of a bulk film, for example pre-metal dielectric layer (PMD) or interlayer dielectric layer (ILD) polishing, where underlying features create recesses and protrusions in the layer surface, and shallow trench isolation (STI) and interlayer metal interconnect polishing, where polishing is used to remove a portion of a via, contact or trench fill material from the exposed surface (field) of the layer having the feature. For example, in interlayer metal interconnect polishing, a conductor, such as tungsten (W) which was deposited in openings in a dielectric film layer is also deposited on the field surface thereof, and the tungsten on the field must be removed therefrom before a next layer of metal or dielectric material can be formed thereover.

After CMP, typically one or more substrates, from a batch or a lot of substrates, are measured or inspected for conformance with process objectives and device specifications. If a substrate film is too thick following some CMP operations (i.e. PMD or ILD), or has a residual undesirable film remaining on the field surface of the substrate, (known as inadequate clearing following a CMP operation such as post metal interconnect or STI polishing), the substrate will typically be returned to the conventional CMP polisher for further polishing. However, post-CMP, the film thickness, and film removal rate, of a substrate may be non-uniform thereacross as a degree of non-uniform material removal across the substrate is inherent in most conventional CMP processes. Thus, reworking of a substrate where the polished layer is too thick or has an undesired residual film thereon may result in film that is too thin at some locations or locations that are over-polished during the rework operation.

In addition to over-polish resulting in a film thickness that is too thin, over-polishing may result in undesirable dishing of the upper surface of a film material in recessed features such as vias, contacts and lines, and/or erosion of the planer surface in areas with high feature density. In addition, over-exposure of a metal such as tungsten (W) to the a metal CMP slurry can result in chemical conversion of the metal by the slurry and thus coring, where the metal fill material no longer adheres to the side wall and base of the opening which it fills, and it pulls away during polishing.

Therefore, there is a need for a method that facilitates removal of materials from specific locations of the substrate with process performance comparable or superior to that of conventional CMP.

### SUMMARY

Embodiments herein generally relate to methods for providing a planarized substrate surface, or a substrate wherein an overburden material is fully cleared from the field surface without dishing of the material filling a hole, or trench, by polishing specific desired locations on a substrate, such as a semiconductor wafer.

In one embodiment, a method of polishing a substrate includes positioning a polishing pad on a substrate at a first radius of the substrate, the polishing pad supported by a support arm and having a contact portion surface area less than a surface area of the substrate and polishing the substrate at the first radius using a first polishing recipe. The first polishing recipe comprises a first polishing dwell time, a first polishing downforce, and a first polishing speed. The method further includes moving the support arm using a positioning motion so that the polishing pad traverses from the first radius to a second radius on the substrate and polishing the substrate at the second radius using a second polishing recipe. The second polishing recipe comprises a second polishing dwell time, a second polishing downforce, and a second polishing speed.

In another embodiment, a method of polishing a substrate urging a polishing pad supported by a first end of a support arm against a surface of a substrate, the polishing pad having a contact portion surface area less than a surface area of the substrate, polishing a first area surface of the substrate, smaller than the surface of the substrate, using a first polishing recipe. The first polishing recipe comprises a first polishing dwell time, a first polishing downforce, and a first polishing speed. The method further includes simultaneously moving the substrate and the support arm so that the polishing pad traverses from a first area surface of the substrate to a second area surface of the substrate smaller than the surface of the substrate and polishing the second area surface of the substrate using a second polishing recipe. The second polishing recipe comprises a second polishing dwell time, a second polishing downforce, and a second polishing speed.

In another embodiment, a method of polishing a substrate includes urging a polishing pad supported by a support arm against a surface of a substrate, the polishing pad having a contact portion surface area less than a surface area of the substrate, simultaneously rotating a chuck that has the substrate secured thereon and moving the support arm so that the polishing pad traverses to each radius of a plurality of radii of the surface of the substrate, and polishing the surface of the substrate using a plurality of polishing recipes, each the plurality of polishing recipes corresponding to each of the plurality of radii. Each of the plurality of polishing recipes comprises a polishing dwell time, a polishing downforce, and a polishing speed.

In another embodiment, a residual film thickness profile is determined based on manual or automated inspection techniques and polishing recipes are generated based on the residual film thickness profile.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a top perspective view of an LSP module according to one embodiment.

FIG. 1B is a schematic cross-sectional view of the LSP module of FIG. 1A.

FIG. 2 is a schematic cross-sectional view of a polishing head according to one embodiment.

FIG. 3 is a schematic cross-sectional view of a polishing pad assembly according to one embodiment.

FIG. 4A is a schematic sectional view of an eccentric member disposed in a polishing head according to one embodiment.

FIG. 4B depicts a polishing motion in accordance with the embodiment of the polishing head depicted in FIG. 4A.

FIG. 5A is schematic sectional view of another eccentric member disposed in a polishing head according to another embodiment.

FIG. 5B depicts the polishing motion in accordance with the embodiment of the polishing head depicted in FIG. 5A.

FIG. 6 is an schematic isometric cross-sectional view of an LSP module according to another embodiment.

FIG. 7 is a schematic plan view of a LSP module showing various motion modes of a polishing pad assembly on a substrate, according to one embodiment.

FIG. 8 is a schematic plan view of a LSP module showing another embodiment of various motion modes of the polishing pad assembly.

FIGS. 9A-9C are illustrations showing polishing paths that produced on a substrate, according to some embodiments.

FIG. 10 is a flow diagram of a method for polishing a substrate, according to one embodiment.

To facilitate understanding, identical reference numerals have been used, where possible, to designate identical elements that are common to the figures. It is contemplated that elements disclosed in one embodiment may be beneficially utilized on other embodiments without specific recitation thereof with respect to the other embodiment(s).

### DETAILED DESCRIPTION

The present disclosure provides a method of polishing a film layer on a substrate using a module particularly suited for location specific polishing (LSP) on the substrate during a fabrication process. The method includes the generation of a thickness correction profile for a film layer on the substrate and the generation of a polishing recipe, or series of polishing recipes, based on the thickness correction profile. In some embodiments, the method may be employed before or after a conventional CMP operation. When the method is used before a conventional CMP operation, in one aspect it is used to selectively remove film layer material, by polishing portions of the exposed film layer, to correct for the existing non-uniform film thickness thereof, and/or to selectively remove film layer material, by polishing portions of the exposed film layer, in anticipation of non-uniform removal of portions of the film layer material during conventional CMP. When the method is used after a conventional CMP operation it is used to correct under-polishing of the film layer surface, or portions of the surface, i.e., inadequate material removal (aka “rework”). Likewise, the equipment and methods herein can be used to correct planarity of a substrate, such as a semiconductor wafer, before processing thereof to form an integrated circuit therewith.

A non-uniform film thickness of a material layer, or the presence of a residual film on the field, following CMP may be a function of film thickness non-uniformity of the film layer before polishing and/or non-uniform material removal during CMP. Material removal non-uniformity is influenced by a number of factors, such as variations in the CMP consumables including the polishing pad structure, the pad surface, substrate retaining rings, pad conditioners, the polishing slurry, polishing process parameters, and substrate properties. The properties of consumables vary from consumable part to part, lot to lot, and manufacturer to manufacturer. Additionally, the effect of the consumable on polishing changes over the lifetime of the consumable. Variations in process parameters which affect resulting film thickness uniformity, and the presence of undesirable residual film on the substrate (inadequate clearing), include deviations in: down force on a substrate, platen and carrier speeds, conditioning forces, platen temperature, and fluid flowrates. Variations in the substrates which effect polishing performance include film layer material properties, film layer level on a multi-level interconnect structure, and/or device size and feature density.

Conventional quality control and in-process monitoring methods are used to reduce incoming consumable and process parameter variation. Changes in material removal non-uniformity profiles across consumable lifetimes and/or due to substrate properties are unavoidable but generally predictable. For conventional CMP systems, configured to polish circular substrates, material removal profiles can often be described with reference to a radial distance from the center of the substrate. Generally, a material removal profile along a diameter of substrate will mirror itself if divided at the center of the substrate. This means that the remaining film thickness, or the presence of a residual film in a particular location on a substrate, is largely dependent on the radius of the location from the center of the substrate and will generally be similar when measured at circumferential locations on the substrate at that same radius.

Monitoring of film thickness or the presence of residual films on production substrates may be done using stand alone, in-line, and in-situ metrology systems as well as post-CMP optical inspection (manual or automated). Measurements and/or inspections may be made before, after, or during conventional CMP, or a combination thereof. For some dielectric film layers, such as pre-metal dielectric layers (PMD) and inter-layer dielectric layers (ILD), post-CMP film thickness, and film thickness uniformity, may be monitored on production substrates for statistical process control (SPC) purposes as well as to ensure compliance with device design specifications.

PMD and ILD post-CMP film thickness is commonly monitored using in-line or stand-alone optical metrology systems. Generally, a specified number of measurements are taken on each substrate, or on a sample number of substrates within a substrate lot (batch of substrates of the same device). Each film thickness measurement is commonly taken within a die or at a dedicated measurement site in a scribe line between dies. The number of measurements, and the corresponding locations, are generally standardized across most or all operations in a semiconductor manufacturing facility including an electrical test operation at the end of a production line which takes electrical measurements of test structures also located in the scribe lines. Matching of measurements taken inline during production with measurements taken at electrical test facilitates SPC and trouble-shooting of the production line, however, these standardized measurement sites may not be ideal for determining a correction profile for use with LSP. One option for determining a correction profile is to take additional measurements across the production substrate beyond the standardized measurements described above.

Metrology throughput and capacity concerns are a factor in how many additional measurements are taken and whether they are taken within a die or at dedicated measurement sites within the scribe lines. The metrology tool may have device pattern recognition capabilities so that the thickness measurement result commonly determines thickness for only the film layer of concern, i.e., the layer just polished, and does not include the thicknesses of underlying layers. Device manufacturers with a changing range of device products, such as foundries, commonly use the dedicated measurement sites in the scribe lines to facilitate automated metrology recipe creation. However, there are fewer dedicated measurement sites on a substrate than there are die, so a correction profile based on these measurement sites may not reflect deviations in film thickness between the measurement sites. Deviations in film thickness between measurement sites may be predicted based on the measurements taken and the process conditions under which the substrate was polished using conventional CMP.

Post CMP monitoring of metal and/or STI properties is done to ensure that metal or STI films are removed from the surface of the substrate but remain in recessed features, such as lines, vias, trenches, or other recesses therein. The presence of residual film is typically the result of under-polishing. Incomplete removal of this film may result in device failure due to shorting (metal CMP) or incomplete transistor formation (STI). Monitoring includes post-CMP thickness measurements of the residual film (i.e. eddy current testing, or optical metrology, for metal and optical metrology for STI) or other optical inspection techniques. Manual optical inspection may comprise a 1× visual inspection of all substrates for residual films and/or a manual inspection under magnification. Automated optical inspection is commonly performed using inline or standalone inspection systems, such as bright field and/or dark field inspection systems.

In some embodiments, film thickness measurements and/or residual film inspection results may be uploaded to a facility automation system where determinations of film layer correction profiles may be made. The facility automation system will generate a polishing recipe based on the correction profile, or may select a polishing recipe based on a known film thickness profile related to the polished film layer, and will then download the correction polishing recipe to the LSP module.

In other embodiments, systems suited for polishing specific locations of a substrate can use information from thickness measurements and/or optical inspections to create a correction profile for a particular substrate. The correction profile is one of a film thickness correction profile and a residual film thickness profile. Predicted post CMP film layer profiles based on consumable lifetime and/or substrate properties, as well as a radial material removal profile of a conventional CMP process and tool, are also useful to improve the accuracy of the correction profile. Polishing recipes based on the correction profile can then be generated for use on the LSP modules disclosed herein, or on any apparatus suitable for selectively polishing discrete portions of a substrate. The polishing recipes may be generated by the LSP module, by a facility automation system, or by some other system. Polishing recipes may be optimized to reduce total correction time using rotational and radial motions of the LSP module.

As will be appreciated by one of ordinary skill in the art, aspects of the present disclosure may be embodied as a system, method, computer program product, or a combination thereof. Accordingly, aspects of the present disclosure may take the form of an entirely hardware embodiment, an entirely software embodiment (including firmware, resident software, micro-code, etc.) or an embodiment combining software and hardware aspects that may be referred to herein as a “circuit,” “module” or “system.” Furthermore, aspects of the present disclosure may take the form of a computer program product embodied in one or more computer readable medium(s) having computer readable program code embodied thereon.

Any combination of one or more computer readable medium(s) may be utilized for storing a program product which, when executed, is configured to perform a method for polishing a substrate. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, radio, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing. Computer program code may be written in any one or more programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The computer program instructions may also be loaded onto a computer, other programmable data processing apparatus, or other devices to cause a series of operational activities to be performed on the computer, other programmable apparatus or other devices to produce a computer implemented process such that the instructions which execute on the computer or other programmable apparatus provide processes for implementing the functions/acts specified in the flowchart and/or block diagram block or blocks.

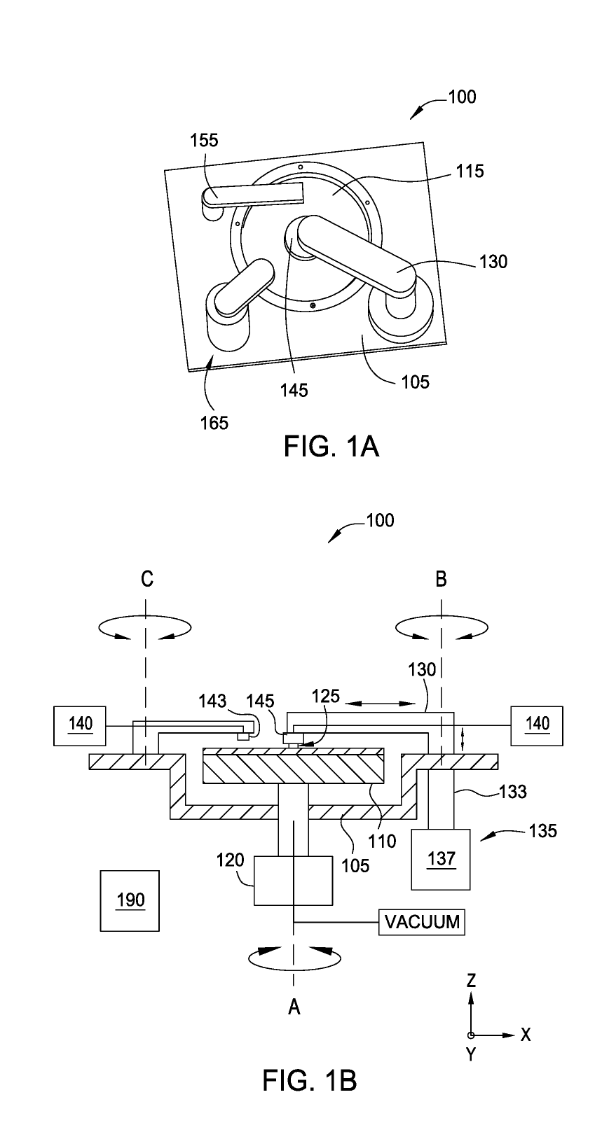

FIG. 1A is a schematic perspective view of an LSP module 100 used to practice the methods described herein. FIG. 1B is a schematic cross-sectional view of the LSP module 100 shown in FIG. 1A. The LSP module 100 includes a base 105 supporting a chuck 110, which rotatably supports a substrate 115 thereon. In the embodiment shown, the chuck 110 is configured as a vacuum chuck, although other substrate securing devices, such as electrostatic, adhesive or clamp based chucks, may be employed. The chuck 110 is coupled to a drive device 120, such as a motor or rotating actuator, providing at least a rotational movement of the chuck 110 about axis A (oriented in the Z direction). The rotational speed of the chuck is desirably between about 0.1 rpm and about 100 rpm, such as between about 3 rpm and 90 rpm.

The substrate 115 is disposed on the chuck 110 in a “face-up” orientation such that a feature (device) side of the substrate 115 faces a polishing pad assembly 125 located thereover. The polishing pad assembly 125 is used to polish or remove material from a specific location of the substrate 115, before or after polishing of the substrate in a conventional CMP system.

The polishing pad assembly 125 is coupled to a polishing head 145 which is, in turn, coupled to a support arm 130 that moves the polishing pad assembly 125 relative to the surface layer of the substrate 115. The support arm 130 is coupled to an actuator system 135. The actuator system 135 herein includes a motor 137 coupled to a support arm shaft 133 which provides rotational motion to the support arm 130 around an axis B. Other embodiments, not shown, may use more than one polishing pad assembly 125, support arm 130, and actuator system 135.

In one embodiment, a fluid applicator 155 is rotatably coupled to the base 105. The fluid applicator 155 includes one or more nozzles 143 to deliver fluids from a fluid source 140 to the surface layer of the substrate 115. The one or more nozzles 143 are selectively positionable over the surface of the substrate 115 by swinging the nozzles 143 of the fluid applicator 155 about a vertical axis C. The fluids delivered through the nozzles 143 facilitate polishing and/or cleaning of the substrate 115 and include a polishing fluid such as a slurry, a buffing fluid, de-ionized water, a cleaning solution, a combination thereof, or other fluids. The base 105 is configured as a basin to collect polishing fluid and/or DIW that has flowed off of the edges of the substrate 115. In another embodiment, the fluid from the fluid source 140 is applied to the substrate through the polishing head. The fluid source 140 may also provide gases to the polishing head, such as clean dry air (CDA) or nitrogen.

Generally, the LSP module 100 includes a system controller 190 configured to control the automated aspects of the LSP module 100. The system controller 190 facilitates the control and automation of the overall LSP module 100 and includes a central processing unit (CPU) (not shown), memory (not shown), and support circuits (or I/O) (not shown). The CPU may be one of any form of computer processors that are used in industrial settings for controlling various processes and hardware (e.g., actuators, fluid delivery hardware, etc.) and monitoring the system processes (e.g., substrate position, process time, detector signal, etc.). The memory is connected to the CPU, and is one or more of a readily available memory, such as random access memory (RAM), read only memory (ROM), floppy disk, hard disk, or any other form of digital storage, local or remote. Software instructions and data are coded and stored within the memory for instructing the CPU to perform one or more polishing process related activities. The support circuits are also connected to the CPU to support the processor in a conventional manner. The support circuits include cache, power supplies, clock circuits, input/output circuitry, subsystems, and the like. A program (or computer instructions) readable by the system controller 190 determines which tasks are performable by the various components in the LSP module 100. Preferably, the program is software readable by the system controller 190, which includes code to generate and store at least substrate positional information, the sequence of movement of the various controlled components, coordinate the movement of various components in the LSP module 100 (e.g., the support arm 130, the polishing pad assembly 125 and the movement of the substrate 115) and any combination thereof. Alternatively, the control of the polishing apparatus can be embodied in a remote controller, computer or other control system, such as a fab wide control system.

In some embodiments, the system controller 190 obtains measurement data or other information concerning the substrate 115 from a metrology station, a factory interface, FAB host controllers, or other devices, and stores the data for determining the correction profile or the residual film profile for the substrate 115. In some embodiments, the system controller 190 stores and executes programs to determine polishing recipe parameters such as polishing dwell time, polishing down force, and polishing speed required for each radius of the substrate 115. The data is stored as formulas, graphs, tables, discrete points, or by other suitable methodology.

In some embodiments, a metrology device 165 (shown in FIG. 1A) is coupled to the base 105. The metrology device 165 is used to provide an in-situ metric of polishing progress by measuring a metal or dielectric film thickness on the substrate 115 during polishing, or detect residual film on the field surface using optical inspection techniques, such as bright field/dark field techniques. The metrology device 165 is one of an eddy current sensor, an optical sensor, or other sensing device useful to determine metal or dielectric film thickness or the presence of a residual film on the field surface. In other embodiments, ex-situ metrology feedback is used to determine post-polishing film layer parameters such as location of thick/thin areas of deposition or residual films on the wafer, and thus the motion recipe for the chuck 110, support arm 130 and polishing pad assembly 125, polishing dwell time, as well as the downforce or pressure of the LSP. Ex-situ feedback can also be used to determine the final profile of the polished film. In situ metrology can be used to optimize polishing by monitoring progress of the parameters determined by ex-situ metrology.

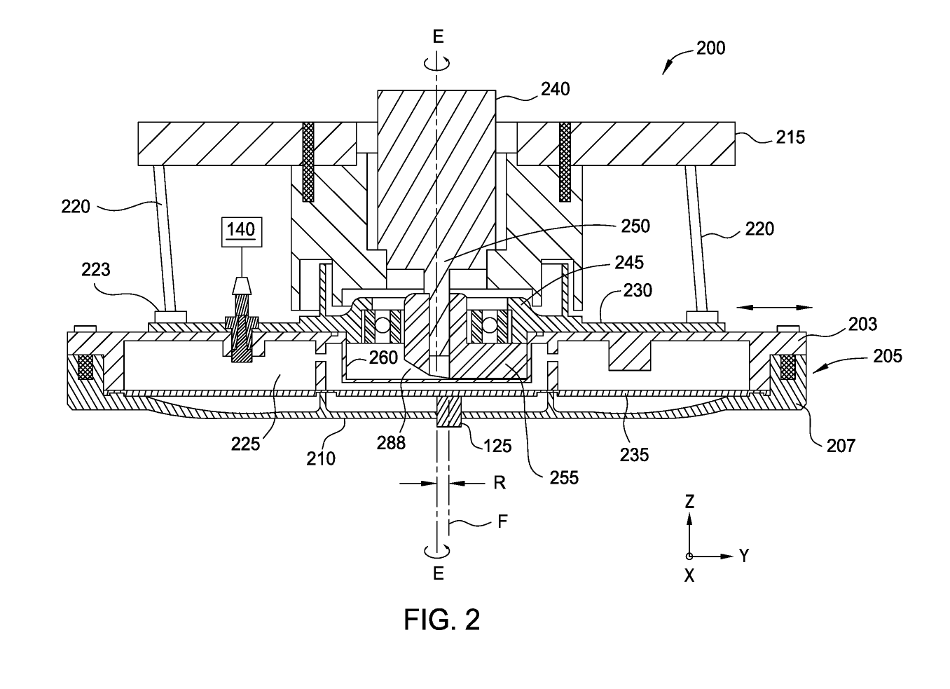

FIG. 2 is a schematic cross-sectional view of one version of a polishing head 200 used to practice the methods described herein. Herein, polishing head 200 is used as the polishing head 145 shown in FIGS. 1A-1B. Polishing head 200 comprises a polishing head housing 205 movably coupled to a support 215 by one or more posts 220 and one or more post couplings 223. The posts 220 and the post couplings 223 maintain a parallel relationship between the support 215 and the polishing head housing 205 and prevent the polishing head housing 205 from rotating relative to the support 215, while allowing for limited lateral motion, such as an orbital motion or an oscillating motion, of the polishing head housing 205 relative to the support 215. In some embodiments, the posts 220 are made of a plastic material, such as nylon. The polishing head housing 205 comprises an upper housing 203 and a lower housing 207. The lower housing 207 is made of a polymer material, such as polyurethane, PET (polyethylene terephytahalate), or other suitable polymers having sufficient hardness and/or strength such as polyether ketone (PEEK) or polyphenylene sulfide (PPS). These materials have sufficient structural strength to maintain their shape under typical CMP process conditions, and are chemically and physically resistant to known CMP fluids and abrasives.

A flexible membrane 235 is movably disposed between the upper housing 203 and the lower housing 207. The flexible membrane 235 and the upper housing 203 define a housing volume 225. The fluid source 140 is fluidly coupled to a gas inlet 280 disposed through the upper housing 203. The fluid source 140 provides a pressurized gas, such as CDA or nitrogen, into housing volume 225. The polishing pad assembly 125 is coupled to the flexible membrane 235 so that the polishing pad assembly 125 protrudes from an opening in the lower housing 207. In operation, the pressurized gas is introduced to the housing volume 225 through the gas inlet 280. The pressurized gas urges the polishing pad assembly 125 against the uppermost layer surface of an underlying substrate (not shown) with a polishing downforce. The polishing downforce of the polishing pad assembly 125 against the surface of the substrate is adjusted by changing the pressure of the gas with in the housing. A pressure controller (not shown) regulates the gas pressure within the housing volume 225 so that the polishing downforce on the polishing pad assembly remains constant through an axial rotation of the polishing head housing 205 relative to the support 215 that results with some embodiments disclosed herein.

In this embodiment, lateral movement of the polishing head housing 205 relative to the support 215 is provided by a shaft 250 coupled to a polishing head motor 240, which rotates the shaft 250 about a vertical axis E. The shaft 250 is coupled to an eccentric member 255, and the eccentric member 255 is rotatably coupled to a bearing 245. The bearing 245 is coupled to the upper housing 203 by a bearing cap 230. An eccentric member housing volume 288 is defined by an inner wall 260 and the bearing cap 230 within which the bearing 245 is piloted, the inner wall 260 surrounding shaft axis E, but offset therefrom. During a polishing operation, the shaft 250 rotates the eccentric member 255 and the eccentric member 255 contacts the inner wall 260 within the eccentric member housing volume 288. The contact of the eccentric member 255 with the inner wall 260 causes the polishing head housing 205 to move laterally and orbitally around axis E relative to the support 215 in a polishing motion. The posts 220 support the polishing head housing 205 below the support 215 and follow the motion of the housing, while limiting the lateral travel of the polishing head housing 205. The polishing motion has a polishing motion radius R of between about 0.5 mm and about 5 mm, such as about +/−1 mm, from the vertical axis E. Herein, the polishing speed is controlled by the rotational speed of the shaft 250. The rotational speed of the shaft 250 is desirably maintained between about 1,000 rpm and about 5,000 rpm.

In another embodiment, the shaft 250 is directly coupled to the polishing head housing 205 and the posts 220 are removed. Here, shaft 250 rotates the polishing head housing 205 relative to the support arm 130. This embodiment may be used to create a rotational polishing motion of the polishing pad assembly relative to the substrate if the vertical axis of the polishing pad assembly is vertical axis E. In another embodiment, the shaft 250 is directly coupled to the polishing head housing 205, the posts 220 are removed, and the center axis F of the polishing pad assembly 125 is offset from vertical axis E so that the rotation of the shaft 250 creates an orbital motion of the polishing pad assembly 125 at a radius R from the vertical axis E (an orbital polishing motion).

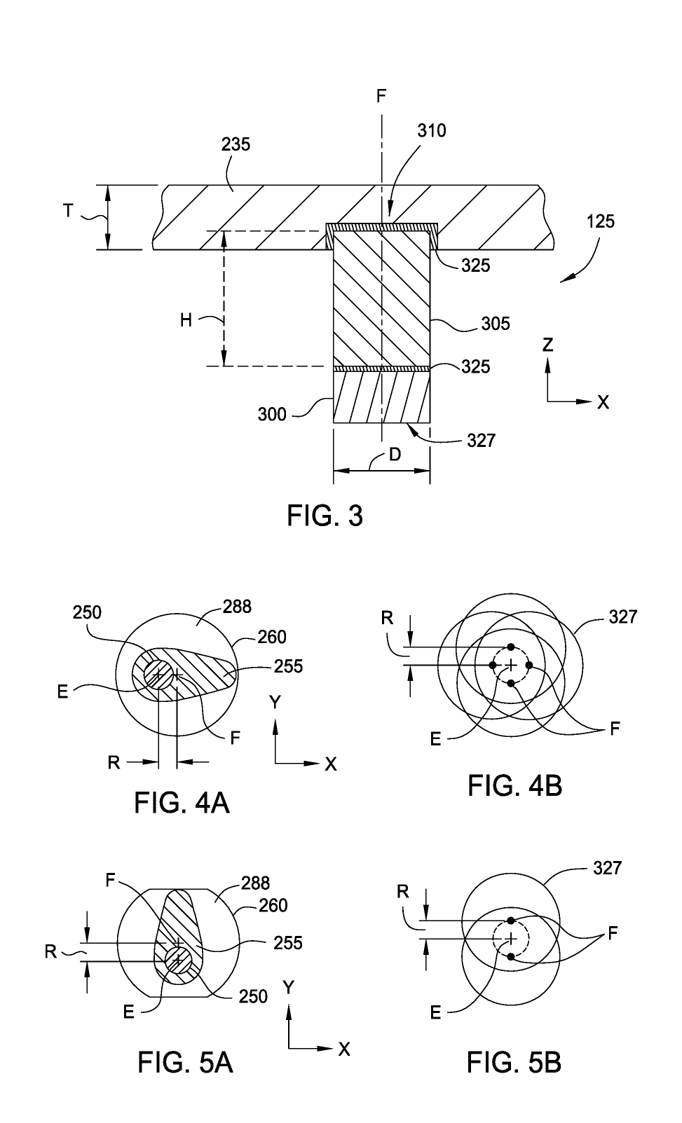

FIG. 3 is a schematic cross-sectional view of the polishing pad assembly 125 and flexible membrane 235 useful to practice the methods described herein. The polishing pad assembly 125 comprises a contact portion 300 and a support portion 305. The contact portion 300 may be a conventional polishing pad material, such as commercially available polishing pad material, for example polymer based pad materials typically utilized in CMP processes. The polymer material includes a polyurethane, a polycarbonate, fluoropolymers, polytetrafluoroethylene (PTFE), polyphenylene sulfide (PPS), or combinations thereof. In some embodiments, the contact portion 300 comprises open or closed cell foamed polymers, elastomers, felt, impregnated felt, plastics, and like materials compatible with the CMP processing chemistries. In some embodiments, the contact portion 300 comprises a polishing pad material available from DOW® that is sold under the tradename IC1010™.

The support portion 305 is a polymer material, such as high density polyurethane, polyethylene, a material sold under the tradename DELRIN®, PEEK, or another suitable polymer having sufficient hardness. The contact portion 300 is coupled to the support portion 305 by an adhesive 325, such as a pressure sensitive adhesive, epoxy, or other suitable adhesive.

The polishing pad assembly is adhered to the flexible membrane 235 by the adhesive 325. In some embodiments, the support portion 305 of the polishing pad assembly 125 is disposed in a recess 310 formed in the flexible membrane 235. In some embodiments, the material used for the flexible membrane 235 has a hardness of between about 55 Shore A and about 65 Shore A. The flexible membrane has a thickness T of between about 1.45 mm to about 1.55 mm and a height H of between about 4.2 mm to about 4.5 mm. The contact surface 327 of the polishing pad assembly 125 has a surface area smaller than the surface area of the uppermost layer of the substrate, such as having an area less than about 5%, less than about 1%, or less than about 0.1% A of the surface area of the uppermost layer of the substrate. For example, for a circular shaped contact surface 327, the diameter D of the polishing pad assembly 125 is about 5 mm, which is an area of about 0.03% of the uppermost surface layer area of a 300 mm diameter substrate. However, in other embodiments, the contact surface 327 may have a different shape and/or a different size.

FIG. 4A is a schematic sectional view of one embodiment of the eccentric member 255 disposed in the eccentric member housing volume 288. FIG. 4B illustrates the path of the orbital polishing motion of the contact surface 327 provided by the embodiment shown in FIG. 4A. In this embodiment, the inner wall 260 forms a circle around an axis F, which herein is also the center of contact surface 327 and which is offset from axis E. Herein, the inner wall 260 is in the shape of a circle and has a radius that is less than a radius formed by eccentric member 255 as it rotates about vertical axis E. As the shaft 250 rotates the eccentric member 255, the eccentric member 255 pushes against the inner wall 260 causing the contact surface 327 to move in an orbital polishing motion relative to the vertical axis E. Herein, the contact surface 327 of the polishing pad assembly 125 is circular and is centered about center axis F, but in other embodiments it may be a different shape. FIG. 4B shows four different positions of center axis F and contact surface 327 as the eccentric member 255 makes one revolution about vertical axis E. The distance between the vertical axis E and the center axis F determines the polishing motion radius R of the contact surface 327. In other embodiments, the polishing motion radius R can be increased by increasing the distance between vertical axis E and the center of the contact surface 327.

FIG. 5A is a schematic sectional view of another embodiment of the eccentric member 255 disposed in the eccentric member housing volume 288. FIG. 5B illustrates an oscillating polishing motion, provided to the contact surface 327, by the embodiment shown in FIG. 5A. In this embodiment, the inner wall 260 is irregularly shaped, as the eccentric member 255 pushes against the inner wall 260 at the two opposite locations that have a radius smaller than the radius formed by the eccentric member 255 it causes the contact surface 327 to move in an oscillating polishing motion. FIG. 5B shows two different positions of center axis F and contact surface 327 as the eccentric member 255 makes one revolution about vertical axis E.

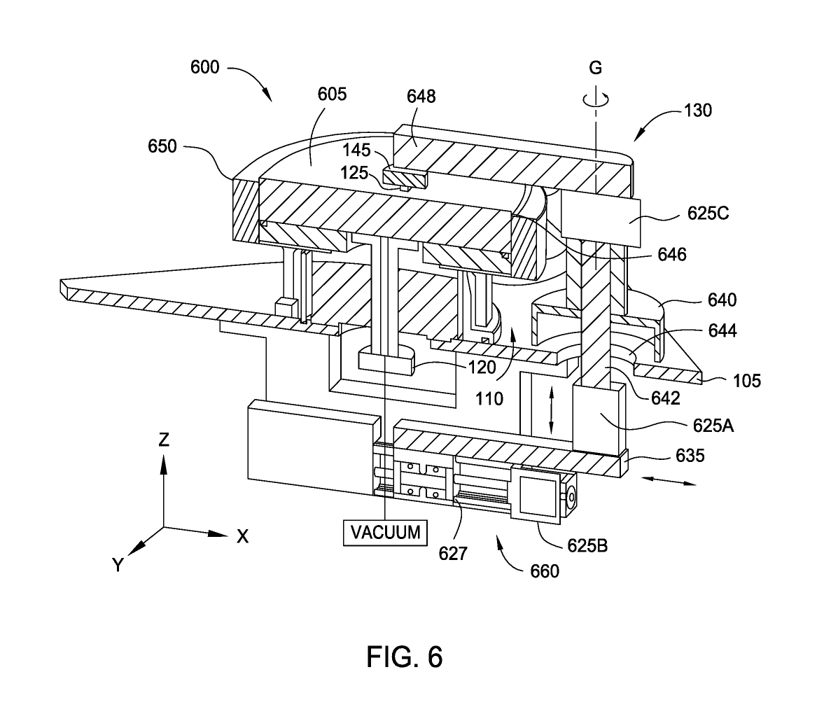

FIG. 6 is a schematic side cross-sectional view of an embodiment of a LSP module 600 used to practice the methods described herein. The LSP module 600 includes the chuck 110 coupled to a vacuum source. The chuck 110 comprises a substrate receiving surface 605 with a plurality of openings (not shown) in fluid communication with the vacuum source to secure a substrate (not shown) thereon. A drive device 120 rotates the chuck 110 around a center vertical axis. The polishing head 145 is coupled to the support arm 130. The polishing head 145 has the structure thereof shown and described with respect to FIG. 1 and the operations described with respect to FIGS. 2 to 5B.

The support arm 130 is movably mounted on the base 105 through an actuator assembly 660. The actuator assembly 660 includes a first actuator 625A and a second actuator 625B. The actuator assembly 660 moves the support arm 130 vertically (Z direction) and laterally (X direction, and thus along the radial direction of the substrate). The first actuator 625A is used to move the support arm 130 (with the respective polishing head 145) vertically (Z direction) the second actuator 625B is used to move the support arm 130 (with the respective polishing head 145) laterally (X direction), and a third actuator 625C is used to move the support arm 130 (with the respective polishing head 145) in a sweep direction (theta direction). The first actuator 625A may also be used to provide a controllable downforce that urges the polishing head towards the substrate receiving surface 605. Other embodiments, not shown, may use more than one polishing pad assembly 125, support arm 130, actuator assembly 660, and third actuator 625C.

The actuator assembly 660 includes a linear movement mechanism 627, such as a lead screw mechanism, a slide mechanism the position of which is controlled by an actuator, or ball screw coupled to the second actuator 625B. Likewise, the first actuators 625A is a linear movement device such as a lead screw mechanism, a slide mechanism the position of which is controlled by an actuator, a ball screw coupled to the support shaft 642, or a cylinder slide mechanism that moves the support arm 130 vertically. The actuator assembly 660 also includes an actuator support arm 635, first actuator 625A and the linear movement mechanism 627. A dynamic seal 640 may be disposed about a support shaft 642 that may be part of the first actuator 625A. The dynamic seal 640 may be a labyrinth seal that is coupled between the support shaft 642 and the base 105. The third actuator 625C includes a motor coupled to the support arm 130 that provides a rotational motion to the support arm 130 around an axis G.

The support shaft 642 is disposed in an opening 644 formed in the base 105, which allows the support arm 130 to move laterally as a result of axial movement of the actuator assembly 660. The opening 644 is sized to allow sufficient lateral movement of the support shaft 642 such that the support arm 130 and polishing head 145 mounted thereon can move from a perimeter 646 of the substrate receiving surface 605 to the center thereof. Additionally, the opening 644 is sized to allow sufficient lateral movement of the support shaft 642 such that the end 648 of the support arm 130 can be located outwardly of the chuck perimeter 650 of the chuck 110. Thus, when the polishing head 145 is moved outwardly to clear the chuck perimeter 650, a substrate can be transferred onto or off of the substrate receiving surface 605 without interference form the polishing head 145. The substrate may be transferred by a robot arm or end effector to or from a conventional polishing station before or after a conventional global CMP process.

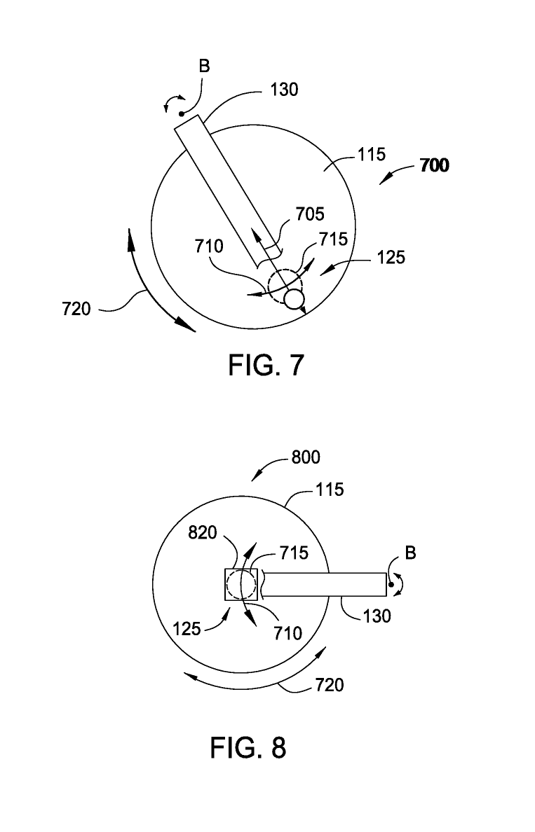

FIG. 7 is a schematic plan view of the motion paradigm of the polishing pad assembly 125 and the substrate in an LSP module 700, showing the positioning of the polishing pad assembly 125 relative to a rotating substrate 115 as described herein. The LSP module 700 may be similar to the LSP modules 100 and 600 shown in FIGS. 1 and 6.

A polishing pad assembly 125 is supported by the support arm 130 of FIG. 6. As shown in FIG. 7, the support arm 130 moves the polishing pad assembly 125 in one of, or a combination of, a radial direction 705 and a sweep direction 715 (theta direction). The rotary motion of the substrate 115, in rotational direction 720 (theta direction), sweeps discrete portions of the substrate 115 under the polishing pad assembly 125. The combined motions of the substrate 115 and the multiple degrees of freedom of motion of the polishing pad assembly 125 facilitate greater control and accuracy for polishing the substrate 115. For example, the combined motions can create an oscillation mode along direction 705 and a circular polishing path. Along the polishing path 715 may, a lateral or random vibration of the polishing pad assembly is provided during polishing of the uppermost layer of the substrate.

FIG. 8 is a schematic plan view of the motion paradigm of an LSP module 800 showing various movements of the polishing pad assembly 125 with respect to the uppermost layer surface of a substrate 115, caused by movement of both the polishing pad assembly and rotation of the substrate 115 during polishing. The LSP module 800 shown in FIG. 8 may be similar to the LSP module 100 and 600 shown in FIGS. 1 and 6.

In one embodiment, the substrate 115 (mounted on the chuck 110 (shown in FIGS. 1A-B and 6) moves in rotational direction 720. The rotational direction 720 can be a back and forth motion (e.g., clockwise and counterclockwise, or vice versa) or a continuous motion in the same direction, clockwise or counterclockwise. The polishing pad assembly 125 is mounted on the support arm 130 and can move on the sweep direction 710 facilitated by the support arm 130 moving about an axis B. While the support arm 130 moves about the axis B in order to move the polishing pad assembly 125 in the sweep direction 710, the polishing pad assembly 125 is moved in a desired way to create a polish path 715. In addition, while the support arm 130 moves about the axis B, and the polishing pad assembly 125 is moved in direction 715, the substrate 115 is moved in the rotational direction 720. In some embodiments, the system controller 190 is configured to coordinate the motion of the support arm 130 and the substrate 115 by controlling the actuators coupled to each. The rotational direction 720 may form an arc or circular shaped path.

The movement of the substrate 115 in the rotational direction 720 has an angular speed that is equivalent to an average rotational speed of between about 0.1 revolutions per minute (rpm) and about 100 rpm in some embodiments. The movement of the support arm 130 in the sweep direction 710 has an angular speed that is equivalent to an average rotational speed of between about 0.1 rpm and about 100 rpm in some embodiments. The movement of the polishing pad assembly 125 in the circular polishing motion 715 has a rotational speed of between about 100 rpm and about 5000 rpm, while the center of the pad is at an offset position from the center of rotation by a distance between about 0.5 mm and about 30 mm, in some embodiments. In some embodiments, a polishing downforce on the polishing pad assembly 125 is provided by a pressurized gas provided to a housing volume 225 of the polishing head 200. The polishing downforce provided to the polishing pad assembly 125 is equivalent to a desirable pressure between about 0.1 psig and about 50 psig.

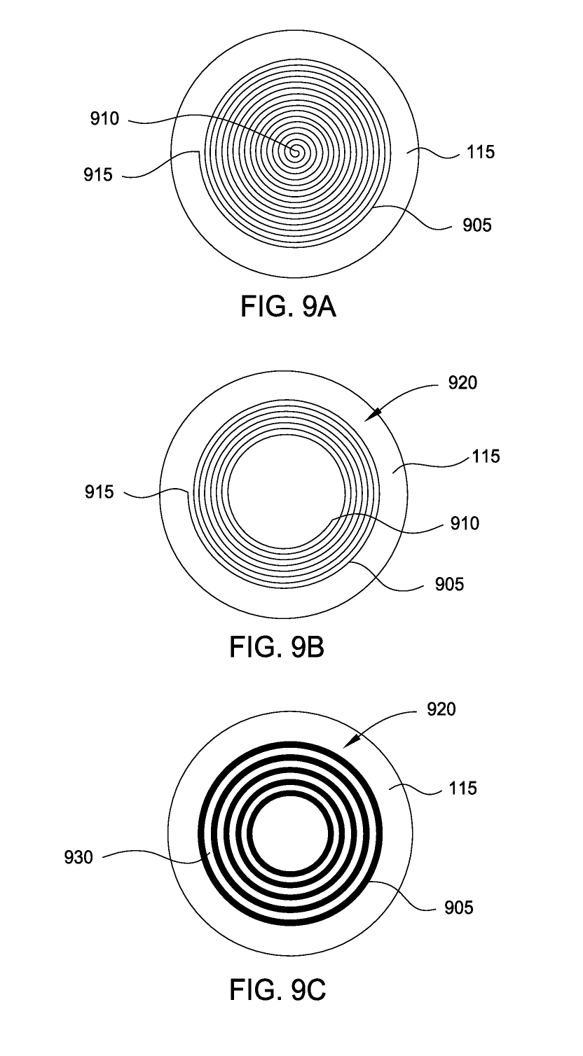

FIG. 9A is an illustration showing a polishing path of the polishing pad assembly 125, according to one embodiment disclosed herein, that may be produced on the substrate 115 using the motion modes shown in FIGS. 7 and 8. In this embodiment, the polishing path 905 is a spiral path starting where the polishing pad assembly 125 is urged against the substrate 115 at a beginning location 910 on the substrate and ending at an ending location 915 on the substrate. The polishing pad assembly 125 is urged against the substrate at the beginning location 910 using a first polishing recipe, the first polishing recipe comprising a polishing dwell time, a polishing downforce, and a polishing speed. As the polishing pad assembly traverses from the beginning location 910 to the ending location 915 it polishes a plurality of intermediate locations using one of a plurality of polishing recipes that correspond to each of the intermediate locations. The polishing downforce on the polishing pad assembly 125 is relieved between the intermediate locations so that the polishing pad assembly is pulled up from the surface of the substrate. In other embodiments the beginning location can be radially outward from the ending location so that the polishing pad assembly travels radially inward towards the center of the substrate. The width of the polishing path 905 is determined by the width of the contact surface area of the polishing pad and the radius of the orbital polishing motion. The polishing path 905 may or may not overlap itself as it traverses from the beginning location 910 to the ending location 915. FIG. 9B is an illustration showing an area polished on the substrate between the beginning location 910 and the ending location 915 that comprises an annular shaped ring, according to another embodiment. FIG. 9C shows one or more polishing paths 905, according to another embodiment. In this embodiment the polishing paths 905 resemble annular rings and a beginning and end of the polishing path may be at a same start stop location 930. The polishing path 905 may be repeated at different radii from the center of the substrate 115 so that the area polished 920 resembles an annular ring. The polishing paths 905 may or may not overlap as they extend radially outwardly.

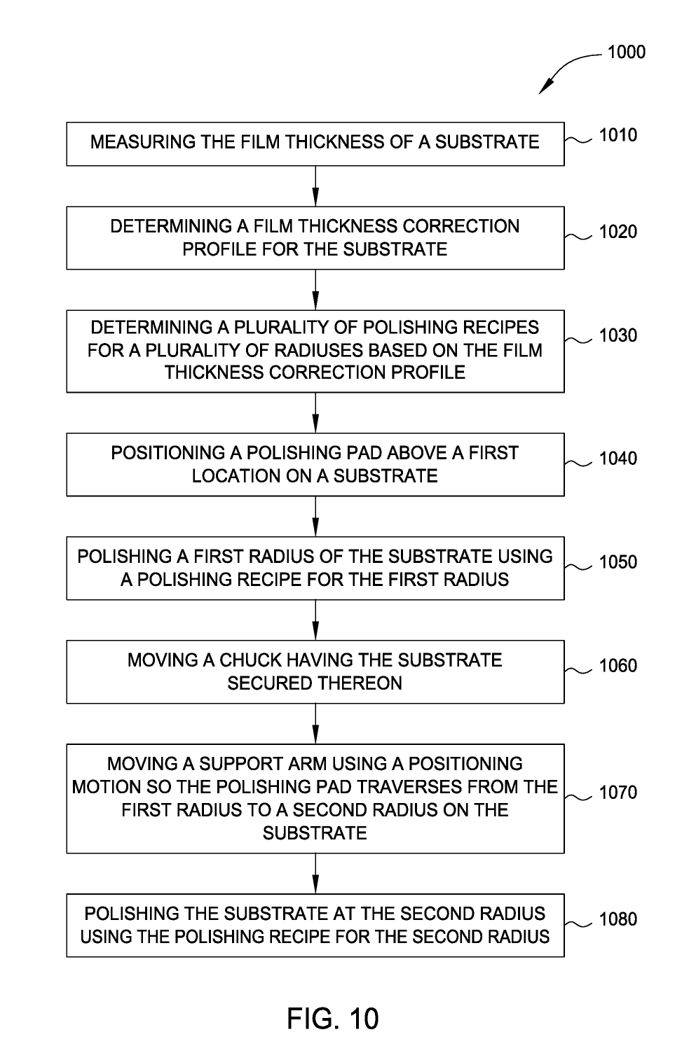

FIG. 10 is a flow diagram of a method for polishing a substrate, according to embodiments described herein. The method provides shorter correction polishing times by minimizing travel distance and travel time between each correction location on the substrate. For example, a substrate requiring material thickness correction of between about 20 Å and 200 Å or about 80 Å may be processed in less than about 10 minutes. It is also believed that the methods described herein improve within die range (WIDR) uniformity and result in improved step height polishing performance comparable to conventional CMP.

In one embodiment, the method 1000 begins at activity 1010 with measuring of the film thickness of a substrate. Measurements may be taken at specified locations on the substrate. In some embodiments, the specified locations may correspond to locations used throughout a device fabrication facility for SPC purposes, for example, at the locations corresponding to a standardized 17 point map for a 300 mm substrate. Each film measurement may be taken within a device die or may be taken at a dedicated measurement site in a scribe line between the die.

The method continues at activity 1020 with determining of a film thickness correction profile for the substrate. Determining the film thickness correction profile is based on the measurements taken in activity 1010 and/or a material removal profile for the substrate based on conventional CMP polishing of the substrate before or after the method disclosed herein. The material removal profile is used to determine a correction profile between the measurement sites of activity 1010. The material removal profile is calculated from predictive modeling or determined using empirical data.

The method continues at activity 1030 with determining a plurality of polishing recipes for the substrate. Each of the plurality of recipes corresponds to a specific area of the substrate, such as an annular ring at a specified radius from a center of the substrate. Each of the plurality of recipes comprises at least one of a polishing downforce, a polishing dwell time, and a polishing motion speed. The polishing downforce is provided by the support arm, by the polishing head, or by another method. The polishing dwell time determines how long a polishing pad or polishing pad assembly remains in a location and how fast it traverses from one location to another. Polishing dwell time comprises the relative velocity of the rotating substrate support chuck, the substrate secured thereon, and the positioning motion of a support arm coupled to the polishing head. Polishing dwell time can be increased by reducing the rotational speed of the chuck, by reducing the rotational speed of the arm, or by a combination of both. Polishing speed comprises the rotational speed of a shaft deposed within the polishing head. Determining the polishing recipe commonly includes determining the polishing downforce, polishing dwell time, and polishing speed to remove a desired thickness of film as determined by the film thickness correction profile.

The method continues at activity 1040 with positioning a polishing pad or a polishing pad assembly at a first radius on the substrate. The first radius is determined from the film thickness correction profile. The polishing pad assembly is positioned by moving the support arm using a positioning motion, by moving the substrate, or by the combination thereof. The positioning motion is provided by rotating the support arm about an axis vertically disposed through a second end of the support arm or by moving the support arm laterally in an X direction, a Y direction, or a combination thereof. The substrate is moved by rotating the substrate support chuck or by moving the chuck laterally in an X direction, a Y direction, or a combination thereof.

The method continues at activity 1050 with polishing at a first radius of the substrate using a polishing recipe for the first radius. In some embodiments, polishing the substrate comprises a polishing motion of the polishing pad or polishing pad assembly, such as an orbital motion, an arcuate motion, a circular motion, an oscillating motion, a rotational motion of the polishing head, or a combination thereof. In other embodiments, the polishing motion is provided by the support arm.

The method continues at activity 1060 with moving the chuck, which has the substrate secured thereon, and at activity 1070 with moving the support arm using the positioning motion so the polishing pad assembly traverses from the first radius on the substrate to a second radius on the substrate. In some embodiments, the first radius is less than the second radius so that the polishing pad moves towards the edge of the substrate as it traverses from the first location to the second location. In other embodiments, the first radius is more than the second radius so the polishing pad assembly moves towards the center of the substrate as it traverses from the first location to the second location.

The method continues at activity 1080 with polishing the substrate at the second radius using a polishing recipe for the second radius.

In some embodiments, the relative motion of the chuck and the positioning motion of the support arm are combined to cause the polishing pad assembly to traverse a spiral shaped polishing path across the surface of the substrate between the first radius and the second radius. In some embodiments, the spiral shaped path does reach the center of the substrate, thus forming an annular ring about the center of the substrate.

In other embodiments, the method begins with inspecting a substrate for a residual film and determining a residual film thickness profile, followed by carrying out the activities of FIG. 10 to polish the upper surface layer of the substrate and selectively remove the residual film. In embodiments that only use an optical inspection technique to inspect for residual metal film, thickness measurements are not available. In those embodiments, a material removal profile is used to determine a residual film thickness profile from the radial location and surface coverage of the residual metal film

The method described above may be used before or after conventional CMP. Benefits of the method include developing highly accurate correction profiles, and corresponding polishing recipes, without increasing the number of measurements needed on a substrate. Polishing recipes based on a radial distance from the center of the substrate minimize total processing time and maximize substrate throughput.

While the foregoing is directed to embodiments of the present disclosure, other and further embodiments of the disclosure may be devised without departing from the basic scope thereof, and the scope thereof is determined by the claims that follow.

1. A method of polishing a substrate, comprising:
positioning a polishing pad on a substrate at a first radius of the substrate, the polishing pad supported by a support arm and having a contact portion surface area less than a surface area of the substrate;
polishing the substrate at the first radius using a first polishing recipe, the first polishing recipe comprising:
a first polishing dwell time;
a first polishing downforce; and
a first polishing speed;
moving the support arm using a positioning motion so that the polishing pad traverses from the first radius to a second radius on the substrate; and
polishing the substrate at the second radius using a second polishing recipe, the second polishing recipe comprising;
a second polishing dwell time;
a second polishing downforce; and
a second polishing speed.

2. The method of claim 1, wherein the polishing pad is coupled to a polishing head and the first polishing speed comprises a rotational velocity of a shaft disposed within the polishing head.

3. The method of claim 1, wherein the positioning motion comprises rotating the support arm around a vertical axis disposed through an end of the support arm.

4. The method of claim 2, further comprising providing a polishing motion to the polishing pad wherein the polishing motion comprises an orbital motion, an arcuate motion, a circular motion, an oscillating motion, a rotational motion, or a combination thereof.

5. The method of claim 3, further comprising supporting the substrate with a chuck, and rotating the chuck around a center axis thereof so that a relative motion of the chuck and the positioning motion of the support arm form a spiral shaped polishing path on the substrate.

6. The method of claim 4, wherein the polishing motion is provided by the polishing head.

7. The method of claim 2, wherein the rotational velocity of the shaft is between about 1000 rpm and about 5000 rpm.

8. The method of claim 1, wherein the contact portion surface area is less than about 1% of the surface area of the substrate.

9. The method of claim 7, wherein an area polished on the substrate between the first radius and the second radius comprises an annular shaped ring.

10. A method of polishing a substrate, comprising:
urging a polishing pad supported by a first end of a support arm against a surface of a substrate, the polishing pad having a contact portion surface area less than a surface area of the substrate;
polishing a first area surface of the substrate, smaller than the surface of the substrate, using a first polishing recipe, the first polishing recipe comprising:
a first polishing dwell time;
a first polishing downforce; and
a first polishing speed;
simultaneously moving the substrate and the support arm so that the polishing pad traverses from a first area surface of the substrate to a second area surface of the substrate smaller than the surface of the substrate; and
polishing the second area surface of the substrate using a second polishing recipe, the second polishing recipe comprising:
a second polishing dwell time;
a second polishing downforce; and
a second polishing speed.

11. The method of claim 10, wherein polishing the first area surface of the substrate and the second area surface of the substrate comprises using a polishing motion.

12. The method of claim 10, wherein moving the support arm comprises rotating the support arm around a vertical axis disposed through a second end of the support arm.

13. The method of claim 10, wherein moving the substrate comprises rotating the substrate around a center thereof such that the polishing pad traverses a spiral shaped path on the substrate.

14. The method of claim 11, wherein the polishing pad is coupled to a polishing head and the polishing motion is provided by an actuator assembly disposed in the polishing head.

15. The method of claim 11, wherein the polishing motion comprises an orbital motion, an arcuate motion, a circular motion, an oscillating motion, a rotational motion, or a combination thereof.

16. A method of polishing a substrate, comprising:
urging a polishing pad supported by a support arm against a surface of a substrate, the polishing pad having a contact portion surface area less than a surface area of the substrate;
simultaneously rotating a chuck that has the substrate secured thereon and moving the support arm so that the polishing pad traverses to each radius of a plurality of radii of the surface of the substrate; and
polishing the surface of the substrate using a plurality of polishing recipes, each the plurality of polishing recipes corresponding to each of the plurality of radii, wherein each of the plurality of polishing recipes comprises:
a polishing dwell time;
a polishing downforce; and
a polishing speed.

17. The method of claim 16, wherein polishing the surface of the substrate comprises providing a polishing motion to the polishing pad, wherein the polishing motion comprises an orbital motion, an arcuate motion, a circular motion, an oscillating motion, a rotational motion, or a combination thereof.

18. The method of claim 16, wherein the polishing pad traverses a spiral shaped path on the substrate.

19. The method of claim 16, wherein the polishing pad is coupled to a polishing head and the polishing speed comprises a rotational velocity of a shaft disposed within the polishing head, wherein the rotational velocity of the shaft is between about 1000 rpm and about 5000 rpm.

20. The method of claim 16, wherein the polishing pad is coupled to a flexible membrane disposed within a polishing head and the polishing downforce comprises a pressurized gas within the polishing head.
